(19) United States
(12) Patent Application Publication
(10) Pub. No.: US 2025/0183000 A1
(43) Pub. Date: Jun. 5, 2025

(54) METHOD OF CHARACTERIZING A FAULT IN A SCANNING ELECTRON MICROSCOPE

(71) Applicant: Carl Zeiss SMT GmbH, Oberkochen (DE)

(72) Inventors: David Laemmle, Darmstadt (DE); Katharina Gries, Darmstadt (DE); Marion Batz, Wiesbaden (DE); Daniel Schwarz, Aalen (DE); Gunther Scheunert, Muenster (DE); Daniel Alexander Emmrich, Darmstadt (DE); Julian Braun, Darmstadt (DE)

(21) Appl. No.: 19/043,613

(22) Filed: Feb. 3, 2025

Related U.S. Application Data
(63) Continuation of application No. PCT/EP2023/071618, filed on Aug. 3, 2023.

(30) Foreign Application Priority Data
Aug. 5, 2022 (DE) 102022119752.2

(51) Int. Cl. H01J 37/244; H01J 37/28

(52) U.S. Cl. CPC H01J 37/244; H01J 37/28; H01J 2237/282

(57) ABSTRACT

A method of characterizing a fault in a scanning electron microscope, wherein the scanning electron microscope is suitable for analysing and/or processing a sample, especially a lithography mask, with the aid of an electron beam, wherein the method has the following steps:
a) putting the scanning electron microscope in an equilibrium state,
b) introducing a trigger event into the scanning electron microscope that disrupts the equilibrium state,
c) detecting a response behaviour of the scanning electron microscope (100) to the trigger event, and
d) comparing the response behaviour detected with an expected response behaviour for characterization of the fault.

### CROSS-REFERENCE TO RELATED APPLICATIONS

This application is a continuation of and claims benefit under 35 U.S.C. § 120 from PCT Application No. PCT/EP2023/071618, filed on Aug. 3, 2023, which claims priority from German Application No. DE 10 2022 119 752.2, filed on Aug. 5, 2022. The entire contents of each of these earlier applications are herein incorporated by reference.

### TECHNICAL FIELD

The present invention relates to a method of characterizing a fault in a scanning electron microscope, to an apparatus and to a computer program product.

### BACKGROUND

Microlithography is used for production of microstructured component parts, for example integrated circuits. The microlithography process is carried out using a lithography apparatus, which has an illumination system and a projection system. The image of a mask (also referred to as reticle or lithography mask) illuminated by use of the illumination system is projected here by use of the projection system onto a substrate, for example a silicon wafer, which is coated with a light-sensitive layer (photoresist) and arranged in the image plane of the projection system, in order to transfer the mask structure to the light-sensitive coating of the substrate.

The mask is used for a multitude of exposures. It is thus very important that it is free of defects. Great efforts are correspondingly made to examine the mask for defects and to repair recognized defects. Defects in such masks can have an order of magnitude in the region of a few nanometers. Repairing such defects necessitates apparatuses which offer a very high spatial resolution for the repair processes.

Suitable apparatuses for this purpose are those that activate local etching or deposition processes on the basis of particle beam-induced processes. For example, EP 1 587 128 B1 discloses such an apparatus. According to this publication, an electron beam from an electron microscope is used to trigger the chemical processes.

The electron beam column in such electron microscopes, especially scanning electron beam microscopes (also “scanning electron microscope” or “SEM” hereinafter), should regularly meet particular stability criteria in order to be able to assure the highly accurate examination and processing of lithography masks described at the outset. The stability criteria include, for example, the beam position or beam profile of the electron beam generated. The stability of the electron beam column may be reduced by various external and internal faults. The external faults include, for instance, fluctuations in temperature or pressure, vibration or the effects of magnetic fields. Internal faults may be caused by altered magnetic fields or altered electrical fields within the electron beam column. A change in electrical fields usually results from contaminations that can change charge.

The clarification of such faults and the alleviation thereof can be complex in practice and, in particular, can take several days. This is applicable in particular when the scanning electron microscope is already in use with a customer, such that the manufacturer of the electron microscope only has limited access thereto.

### SUMMARY

Against this background, it is an aspect of the present invention to provide an improved method, in particular a rapid and targeted method, of characterizing a fault in a scanning electron microscope.

Accordingly, a method of characterizing a fault in a scanning electron microscope is provided, wherein the scanning electron microscope is suitable for analyzing and/or processing a sample (also termed “probe”), especially a lithography mask, with the aid of an electron beam, wherein the method has the following steps: a) introducing a trigger event into the scanning electron microscope, b) detecting a response behaviour of the scanning electron microscope to the trigger event, and c) comparing the response behaviour detected with an expected response behaviour for characterization of the fault.

In this way, it is possible to quickly and easily characterize faults in a scanning electron microscope.

Herein, instead of a scanning electron microscope, any focused particle beam system may be used, for example a helium ion microscope.

For example, the present method or a method according to a further aspect may have one or more of the following steps: i) recording SEM images of a reference object that does not move within the chamber of the electron beam column; ii) calculating an offset of the SEM images recorded (image offset corresponds to the change in position of the electron beam); iii) comparing the image sharpness of the SEM images recorded; iv) calculating the change in parameters of the electron beam column such as focus, stigmator or aperture (if appropriate by optimization of these parameters by what are called auto functions); v) introducing a trigger event; repeating steps i) to v).

In one embodiment, the scanning electron microscope, prior to step a), is put in an equilibrium state, where the trigger event in step a) is such that it disrupts the equilibrium state.

The inventors have found that, surprisingly, faults can be visualized particularly efficiently in that the scanning electron microscope, especially the electron beam column thereof, is put out of its equilibrium state and then the response behaviour is detected and analyzed. One advantage of this approach is that control of the scanning electron microscope is simplified in this approach, since it is always possible to, e.g., record an image of a reference object. If, by contrast, a trigger event were merely to be introduced into the scanning electron microscope without bringing it into an equilibrium state beforehand, such an image can or may be utilized only with difficulty, if at all, as a basis for the analysis of response behaviour.

An equilibrium state in the present context is understood to mean a state of the scanning electron microscope in which an electron dose in the beam path of the electron beam column is constant over time. This means that the electron dose at a site O1 at a time t1 corresponds to the electron dose at site O1 at another time t2, meaning that these are the same or essentially the same, or that, in the case of a periodic process, an electron dose in the beam path of the electron beam column is constant on average over time. The electron dose is determined as a function of current and voltage.

The sample is especially a lithography mask, i.e. a mask intended for use in a lithography apparatus. This may especially be an EUV or DUV lithography apparatus. EUV stands for “extreme ultraviolet” and refers to a wavelength of the working light of between 0.1 nm and 30 nm. DUV stands for “deep ultraviolet” and refers to a wavelength of the working light of between 30 nm and 250 nm.

In one embodiment, for the putting of the system into the equilibrium state, a number N of images is recorded, where N is preferably greater than 3, further preferably greater than 10.

The recording of a number N of images (especially of a reference object) can establish and maintain the equilibrium state of the scanning electron microscope in a simple manner. For example, an image may be taken for ten seconds every two minutes.

During this time, the electron beam reaches a reference object. For the rest of the time, i.e. for 1 min and 50 s, the electron beam is steered on to a stop of the scanning electron microscope, for example with the aid of an electrostatic or magnetic deflector.

In particular, it may be the case that the period of time envisaged for the recording of each one of the N images is less than the period of time between two successive images.

The reference object is, for example, a lithography mask, a dissolution sample or other sample with structures in the nm region, a Faraday cup with structures in the nm region or a shielding element (especially a mesh, as described, for instance, in DE 10 2020 124 306) for charge compensation, which prevents the charging of the sample (especially lithography mask) in normal operation.

In a further embodiment, the putting of the system into the equilibrium state comprises recording a position and/or a sharpness of the electron beam as a function of time and comparing it with a threshold value, with commencement of step a) being dependent on the comparison.

It can be concluded from the comparison of the aforementioned parameters with the threshold value that the scanning electron microscope is indeed in an equilibrium state. If this is the case, it is possible to commence the trigger event. Alternatively, the step of putting the system in the equilibrium state may be such that a predefined operation is performed (for instance the above-described recording of the images), followed by a predefined wait time. In this way, it is likewise possible to ensure that an equilibrium state is attained. Only thereafter does step a) commence.

In a further embodiment, the response behaviour detected in step b) is a position, a sharpness, a focus, a stigmator and/or a coma of the electron beam, especially as a function of time.

The focus in the present context is understood to mean a beam diameter of the electron beam. The stigmator describes a variance of the beam cross section in two mutually orthogonal directions. The coma describes a deformation of the electron beam that results from passage of the electron beam through a lens outside the optical axis. The change in position with time is also referred to as “drift”.

Such response behaviour can be detected in a simple manner, especially in an image of the reference object generated by the scanning electron microscope. The response behaviour can thus be generated via the image information that arises in the imaging of a spatially invariable reference object: for this purpose, the offset of individual elements in the image or of the complete image with respect to its predecessor or another reference is used to determine the change in position. In order to determine the parameters that change image sharpness (focus, stigmation and coma), it is possible to employ either comparison of the changed images themselves or comparison of processed images (evaluation of the Fourier spectrum or the like), or it is possible to optimize the electron beam, in which a new optimum is found by the recording of multiple images with altered beam properties.

In a further embodiment, the trigger event comprises: an altered sample current, an altered acceleration voltage, parts of switch-on sequences, a change in a process gas composition or a process gas pressure and/or a change in the electron beam cross section or in a position of the electron beam.

In principle, any adjustment to the electron microscope is a possible trigger if the change causes an altered electron dose or an altered electron energy. This includes variation of lens currents for expansion and focusing of the electrons at any particular point in the system, variation of acceleration voltages and other voltages in the system, or variation of the deflection of electrons by use of deflection coils of electrostatic deflectors, mechanical elements and the emission source.

The sample current is understood to mean a detected current of the electron beam in the region of the sample.

Parts of switch-on sequences are understood to mean the switching-off and/or -on of acceleration voltages, closing/opening of valves etc.

Appropriate process gases suitable for depositing material or for growing elevated structures are, in particular, alkyl compounds of main group elements, metals or transition elements. Examples thereof are (cyclopentadienyl)trimethylplatinum CpPtMe₃ (Me=CH₄), (methylcyclopentadienyl)trimethylplatinum MeCpPtMe₃, tetramethyltin SnMe₄, trimethylgallium GaMe₃, ferrocene Cp₂Fe, bis-arylchromium Ar₂Cr, and/or carbonyl compounds of main group elements, metals or transition elements, such as, for example, chromium hexacarbonyl Cr(CO)₆, molybdenum hexacarbonyl Mo(CO)₆, tungsten hexacarbonyl W(CO)₆, dicobalt octacarbonyl CO₂(CO)₈, triruthenium dodecacarbonyl Ru₃(CO)₁₂, iron pentacarbonyl Fe(CO)₅, and/or alkoxide compounds of main group elements, metals or transition elements, such as, for example, tetraethyl orthosilicate Si(OC₂H₅)₄, tetraisopropoxytitanium Ti(OC₃H₇)₄, and/or halide compounds of main group elements, metals or transition elements, such as, for example, tungsten hexafluoride WF₆, tungsten hexachloride WCl₆, titanium tetrachloride TiCl₄, boron trifluoride BF₃, silicon tetrachloride SiCl₄, and/or complexes comprising main group elements, metals or transition elements, such as, for example, copper bis(hexafluoroacetylacetonate) Cu(C₅F₆HO₂)₂, dimethylgold trifluoroacetylacetonate Me₂Au(C₅F₃H₄O₂), and/or organic compounds such as carbon monoxide CO, carbon dioxide CO₂, aliphatic and/or aromatic hydrocarbons, and the like.

Appropriate process gases suitable for etching material are for example: xenon difluoride XeF₂, xenon dichloride XeCl₂, xenon tetrachloride XeCl₄, water vapour H₂O, heavy water D₂O, oxygen O₂, ozone O₃, ammonia NH₃, nitrosyl chloride NOCl and/or one of the following halide compounds: XNO, XONO₂, X₂O, XO₂, X₂O₂, X₂O₄, X₂O₆, where X is a halide. Further process gases for etching material are specified in the present applicant's U.S. patent application Ser. No. 13/103,281, filed on May 9, 2011, and issued as U.S. Pat. No. 9,721,754 on Aug. 1, 2017.

In a further embodiment, steps a) to c) (optionally including the step of putting the system in the equilibrium state) are conducted for a first trigger event and repeated for a second trigger event, wherein the first and second trigger events are chosen such that an electron dose at the first site within the beam path of the electron beam has a first value on occurrence of the first trigger event and has a second value different from the first value on occurrence of the second trigger event, and an electron dose at a second site within the beam path of the electron beam has a first value on occurrence of the first trigger event and a second value equal to the first value on occurrence of the second trigger event, wherein, in a step that follows step c), the fault is assigned to the first site depending on the comparison in step c) for the first and second trigger events.

In other words, this embodiment is based on the finding that the fault can be localized in that two different trigger events are configured such that—by way of the electron dose introduced—they bring about a change in a target region (first site), but this has the effect that a change likewise takes place at one or more other sites (side effect). Because the site of the fault can thus be localized, a repair can be targeted, or it is possible, for instance, to change the correct parts of the electron beam column.

In a further embodiment, the first trigger event comprises focusing of the electron beam by use of an anode stop and/or aperture stop, wherein the sample current is collected in a Faraday cup, and the second trigger event comprises trimming the electron beam with the aid of the anode stop and/or aperture stop, wherein the sample current is likewise collected in the Faraday cup.

For example, depending on the electron beam column, the sample current (the “sample current” in the present context means the electron current toward the reference object) may be generated by the change in lens currents that focus the beam through a stop (high current) or expand the beam before the stop (low current). In other systems, the electron beam is directed through smaller or larger stops, for example through stop slides or through multi-aperture stops, and electromagnetic deflectors that steer the beam through the desired stop.

The use of a Faraday cup in the construction, in embodiments, allows the electron dose in the system to be altered such that the electron beam for the image recording is steered to the edge of the Faraday cup. For the trigger, the electrons are steered into the Faraday cup.

In a further embodiment, the first trigger event comprises a change in current at the electron beam source for generation of the electron beam and the second trigger event comprises an increase in the sample current with the aid of a condenser excitation.

In a further embodiment, the first trigger event comprises passage of the electron beam through a stop and the second trigger event comprises an increase in the sample current.

“Stop” here refers, for example, to a multi-aperture stop in the case of a single condenser or a single-aperture stop in the case of a double condenser.

In a further embodiment, the first trigger event comprises complete covering of the electron beam at the stop and the second trigger event comprises collecting of the electron beam in a Faraday cup.

The above-described variants show a skillful selection for the first and second trigger events with high significance for the error site or the site of the fault.

In a further embodiment, the response behaviour in steps b) and/or c) comprises a vertical displacement or jump and/or decay characteristics or transient response.

The vertical displacement (especially in terms of its magnitude) or else the decay characteristics (for example the time until the parameter detected has gone below a defined threshold) can be evaluated in a simple manner.

In one embodiment, steps a) to c) (optionally including the step of putting the system in an equilibrium state) are fully automated.

This allows the method to be performed rapidly, specifically in situ by the customer of the scanning electron microscope manufacturer.

According to a further aspect, a computer program product is provided, comprising commands which, when the program is executed by a computer, cause the latter to execute the method as described above.

A computer program product, for example a computer program medium, can be provided or supplied, for example, as a storage medium, for example a memory card, a USB stick, a CD-ROM, a DVD, or else in the form of a downloadable file from a server in a network. By way of example, in a wireless communications network, this can be effected by transferring an appropriate file with the computer program product or the computer program means.

The embodiment or features described above for the present methods are correspondingly applicable to an apparatus (described hereinafter) and to the computer program, and vice versa.

“A” or “an” in the present case should not necessarily be understood to be restrictive to exactly one element. Instead, a plurality of elements, for example two, three or more, may also be provided. Nor should any other number used here be understood to the effect that there is a restriction to exactly the stated number of elements. Instead, unless indicated otherwise, numerical deviations upward and downward are possible. In addition, the method steps described may also be executed in a different sequence, for example first step b), then step a), in the absence of any statement to the contrary.

Further possible implementations of the invention also include combinations, not mentioned explicitly, of features or embodiments described above or hereinafter with respect to the exemplary embodiments. In this case, a person skilled in the art will also add individual aspects as improvements or supplementations to the respective basic form of the invention.

### BRIEF DESCRIPTION OF DRAWINGS

Further advantageous configurations and aspects of the invention are the subject of the dependent claims and also of the exemplary embodiments of the invention that are described hereinafter. The invention is elucidated in detail hereinafter on the basis of preferred embodiments with reference to the appended figures.

FIG. 1 shows a schematic view of a processing arrangement for checking and/or repair of a lithography mask;

FIG. 2 shows an electron beam column of the processing arrangement from FIG. 1;

FIG. 3 shows a flow diagram of a method according to one embodiment;

FIG. 4 shows a flow diagram of a further method according to one embodiment;

FIG. 5 shows an illustration of a wafer inspection or metrology system for 3D volume inspection with a dual beam device;

FIG. 6 shows an illustration of the slice-and image method of a volume inspection in a wafer; and

FIG. 7 shows a wafer inspection system according to an embodiment.

### DETAILED DESCRIPTION

Elements that are identical or functionally identical have been provided with the same reference signs in the figures, to the extent that one is specified. It should also be noted that the representative figures are not necessarily true to scale.

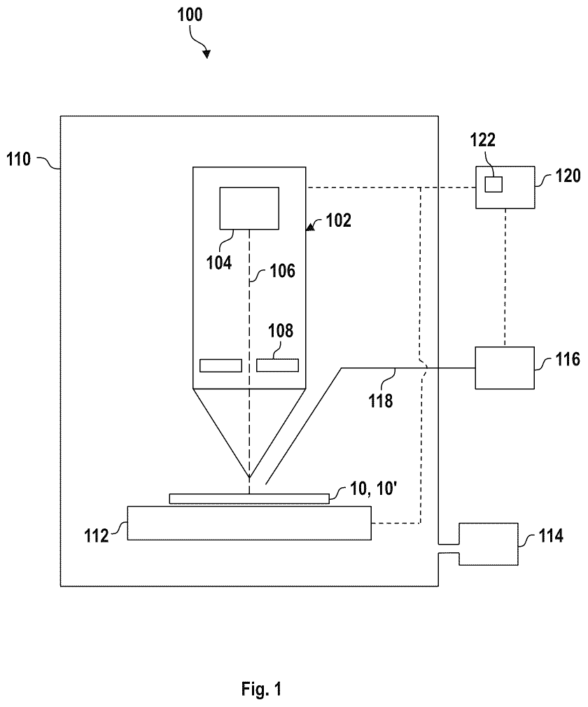

FIG. 1 shows a schematic of a working example of a processing arrangement 100 (also termed “apparatus” herein), in the form, for example, of a scanning electron microscope. The processing arrangement 100 serves to check and/or to repair a sample, for example a lithography mask 10. The lithography mask 10 is intended, for example, for use in an EUV or DUV lithography apparatus (not shown).

The processing arrangement 100 comprises an electron beam column 102. This has an electron source 104 that produces an electron beam 106. The electron beam 106 hits the lithography mask 10. Backscattered electrons are detected by a detector unit 108 of the electron beam column 102. It is thus possible to create a high-resolution image of the lithography mask 10 (electron beam microscope).

The electron beam column 102 is disposed within a vacuum housing 110. The same applies to the lithography mask 10 which is disposed on a sample stage 112 beneath the electron beam column 102. The vacuum within the vacuum housing 110 is generated with the aid of a vacuum pump 114. For example, there is a residual gas pressure of 10⁻⁷ mbar to 10⁻⁸ mbar within the vacuum housing 110.

The electron beam column 102 can interact with process gases fed in, which are fed, for example, by a gas provision unit 116 from the outside via a gas conduit 118 into the region of a focal point of the electron beam 106, in order to perform electron beam-induced processing (EBIP) operations. This especially encompasses deposition of material on or etching of material from the lithography mask 10. In particular, a control computer 120 of the processing arrangement 100 is configured to control the electron beam column 102, the sample stage 112 and the gas provision unit 116 in a manner suitable for this purpose.

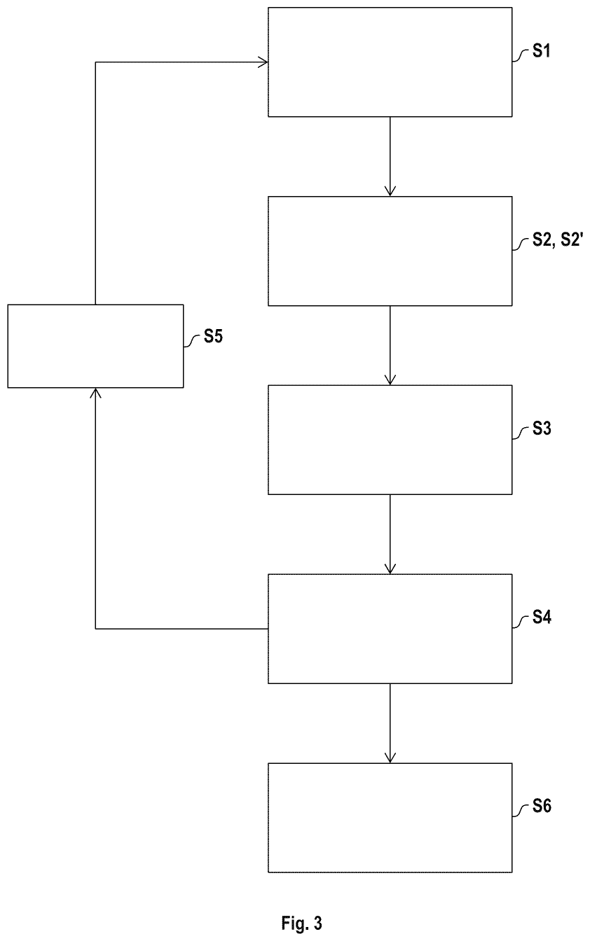

In particular, a computer program 122 is recorded on the control computer 120, which actuates the processing arrangement 100 to execute the method described in detail hereinafter in association with FIG. 3.

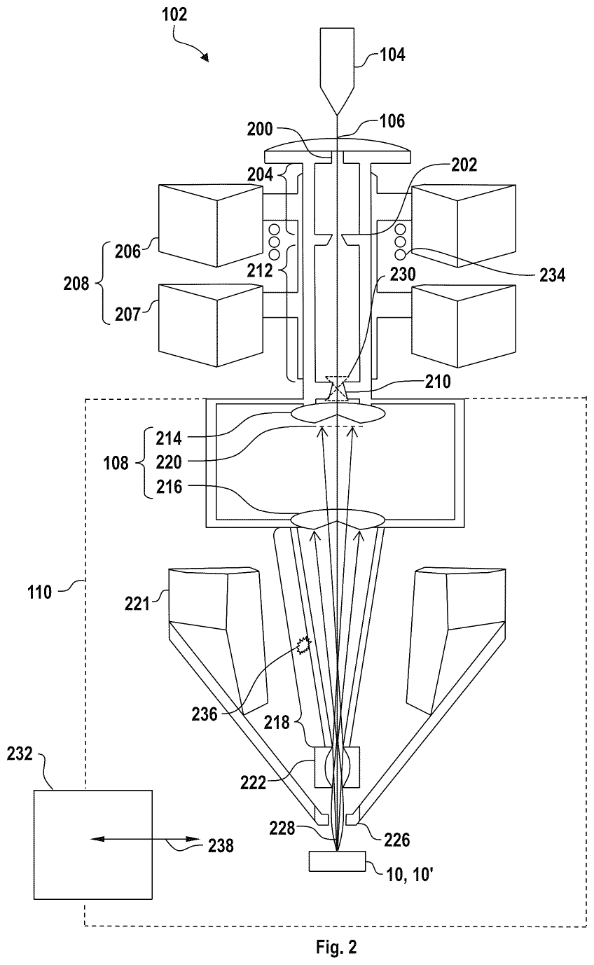

FIG. 2 shows the electron beam column 102 from FIG. 1 in greater detail. By comparison with FIG. 1, FIG. 2 also shows that the electron beam column 102 of the electron source 104 includes an anode aperture 200 disposed downstream in the beam path. The anode aperture 200 is followed, in the beam path, by an aperture stop 202 with a single opening. Assigned to the beam path section 204 between the anode aperture 200 and the aperture stop 202 is a first condenser 206 of a double condenser 208. The aperture stop 202 is followed by a further stop 210. The beam path section 212 between the aperture stop 202 and the further stop 210 (which may, for instance, be a pressure-stage stop) is surrounded by a second condenser 207 of the double condenser 208. The stop 210 is followed in the beam path by the detector unit 108 already mentioned in connection with FIG. 1. In detail, this may comprise an ESB (energy-selective backscatter) detector 214 and an SE (secondary electron) detector 216, and a filter grid 220 may be disposed between the two. The further beam path section 218 that follows the detector unit 108 is surrounded by a magnetic lens 221. The electron beam 106 is ultimately directed out of the electron beam column 102 onto the lithography mask 10 (or a reference object 10′ in the method described hereinafter) via scanner coils 222 that are responsible for the scanning of the lithography mask 10, and an electrostatic lens 226.

The above-described construction of the electron beam column 102 should be considered to be purely illustrative and may have different designs in various regions. For example, a single condenser may be provided rather than the double condenser 208.

With reference to FIG. 3, a flow diagram is described hereinafter, which shows one embodiment of a process sequence. This process sequence may especially be implemented by the computer program 122 described in connection with FIG. 1 in the processing arrangement 100.

In an optional step S1, the scanning electron microscope 100 is put in an equilibrium state. This can be effected, for example, in that the scanning electron microscope 100, with the aid of the detector unit 108, records a number N of images, especially of a reference object 10′, in the chamber of the scanning electron microscope 100 which is not shown in detail, where N is preferably greater than 3, further preferably greater than 10. The time taken to record an image may, for example, be 10 s, with an interval between the images of 1 min 50 s. These values are merely illustrative and may be matched to the respective application. Typically, a scanning electron microscope 100 reaches an equilibrium state after recording 3 to 10 images.

It is possible to check in step S1 that such an equilibrium state has indeed been achieved by detecting a position and/or sharpness of the electron beam 106 (see FIGS. 1 and 2) as a function of time and comparing them with a threshold value. If, for example, the drift is below the defined threshold, this ensures that the equilibrium state has been attained, and so the method can progress to step S2.

In step S2, a trigger event is introduced into the scanning electron microscope 100 that disrupts the equilibrium state. This means that the scanning electron microscope 100 or in particular the electron column 102 thus goes out of equilibrium. What this means, for example, is as follows:

While, in the equilibrium state, the electron dose in a particular beam path section 204, 212, 218 illustrated in FIG. 2 is constant over time, or on recording of each of the N images (meaning, for example, that the electron dose in the beam path section 204 during the recording of the first of the N images is equal to the electron dose in the beam path section 204 during the recording of the second of the N images), the electron dose in a particular beam path section 204, 212, 218 varies over time when the equilibrium state has been disrupted. For a particular section, the electron beam dose may be calculated from the electron current and the electron voltage for example.

A possible trigger event is, for example, an altered sample current, an altered acceleration voltage, parts of switch-on sequences, a change in a process gas composition or a process gas pressure or a change in the electron beam cross section or in a position of the electron beam.

In the further method step S3, the response behaviour of the electron beam microscope 100 or of the electron beam column 102 is detected. For example, with the aid of the detector unit 108 (see FIGS. 1 and 2), a position, a focus, a stigmator and/or a coma of the electron beam 106 may be detected. In particular, it is also possible to detect or calculate a derivative of the aforementioned parameters in step S3. In the subsequent step S4, the detected response behaviour is compared with an expected response behaviour. The fault is characterized on the basis of the comparison.

The expected response behaviour is recorded, for example, in tests that precede the method according to steps S1 to S4, especially before the scanning electron microscope 100 is delivered to a customer. It is possible to conclude particular faults from the comparison of the detected with the expected response behaviour. This correlation may in turn be examined in experiments and the like prior to performance of the method according to steps S1 to S4, especially before the scanning electron microscope is supplied to the customer. This experience-based knowledge can then be included in the determination of the fault in step S4. For example, the fault may be a contamination in one of the beam path sections 204, 212, 218. Such a contamination has a predetermined effect on the response behaviour of the electron beam column 102. In particular, in step S4, it is possible to examine the response behaviour in relation to vertical displacement and/or decay characteristics.

Skillful selection of the trigger events also allows the fault to be localized. For this purpose, the method according to steps S1 to S4 is conducted for a first trigger event and then repeated for a second trigger event, as indicated by method step S5. The first and second trigger events are chosen, for example, such that an electron dose in the beam path section 204 (FIG. 2) has different values. By contrast, the electron dose in the other beam path sections—identified here by way of example by reference numerals 212 and 218—of the electron beam column 102 remains constant. In a method step S6 that follows method step S4, it can be concluded therefrom that, if a fault has been detected for the first trigger event in method step S4 but no such fault is detected for the second trigger event (in step S4 in the repetition of steps S1 to S4), the fault or its cause must lie in beam path section 204. The reason for this is that the conditions (electron beam dose) in the other sections of the electron beam column 102 are unchanged. Reversal of charge must thus have occurred in electron beam section 204. A corresponding evaluation as shown in tabular form below can thus be effected in method step S6:

| First trigger | Second trigger | Evaluation result |
|---|---|---|
| event | event | according to method step S6 |
| Fault | No fault | Fault at the target site |
| Fault | Fault | Fault at another site |
| No fault | No fault | No fault or fault at another |
| | | site |
| No fault | Fault | Invalid measurement, e.g. |
| | | external random fault |

The second trigger event may also be referred to as discriminator because it helps in the classification of the fault detected for the first trigger event, for example as an actual fault, no fault or an invalid measurement, and also as assignment of the fault detected for the first trigger event to a particular site in the electron beam column 102.

The inventors have found that subsequent trigger events lead to surprisingly good results with regard to the local determination of the fault:

For example, for the first trigger event, the electron beam 106 is focused through the anode stop 200 (see FIG. 2) or the aperture stop 202. The sample current 228 does not hit the sample 10, but is collected in a Faraday cup 10′. Because of the focusing of the electron beam 106, it is not trimmed by the anode stop or aperture stop 200, 202. The second trigger event, by contrast, envisages trimming of the electron beam 106 by the anode stop and/or aperture stop 200, 202. The sample current 228 is likewise collected in a Faraday cup. This ultimately alters only the electron dose in the beam path section 204 (comparing the first trigger event with the second trigger event). By contrast, the electron dose in sections 212, 218 and in all other regions remains constant within the electron beam column 102.

A further favourable trigger event (first trigger event) has been found to be a change in current in the electron source 104. The second trigger event in this case comprises an increase in the sample current 228 with the aid of the condensers. For this purpose, the electron beam is focused by the stop 210 with the aid of a condenser lens (especially a first) for example.

A further first trigger event envisages passage of the electron beam 106 through the stop 210. The second trigger event increases the sample current 228. For example, the sample current is altered with the aid of a multi-aperture stop having different diameters. Alternatively, the beam diameter is altered on passage through the stop 210, for instance via elevated excitation in the condenser lens.

In a further variant, the first trigger event includes complete coverage of the electron beam 106 at the stop 210. In the second trigger event, the electron beam 106 is collected in the Faraday cup.

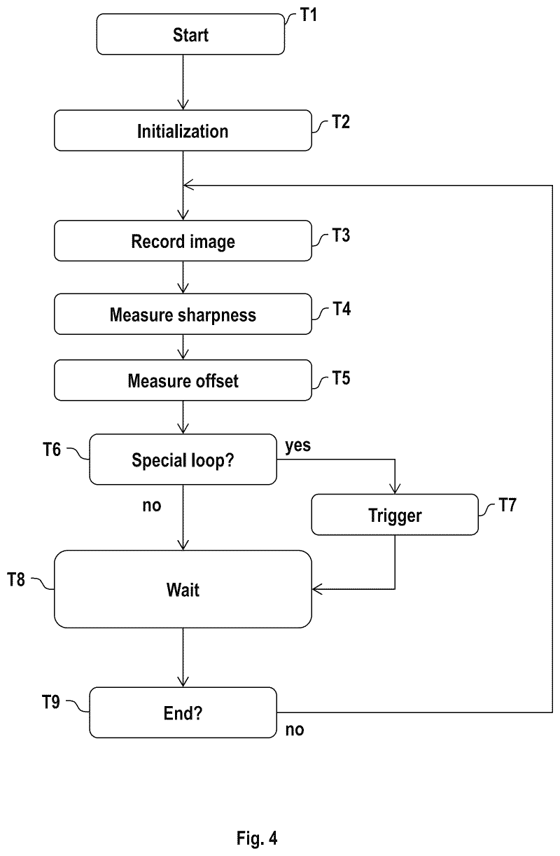

FIG. 4 shows one possible implementation of the method described in connection with FIG. 3. In the method according to FIG. 4, in a step T1, a repair mode or wait mode of the electron beam microscope 100 is started. In a step T2, the electron beam microscope 100, especially the electron beam column 102, is initialized. In a step T3, with the aid of the detector unit 108, an image of the sample 10 is recorded. In step T4, a sharpness of the image detected is measured. In step T5, an image offset is measured. In step T6, a decision is made as to whether a trigger event according to step T7 is to be initiated. This is done (“yes”) if it is found that the electron microscope 100 is in an equilibrium state. If this is not yet the case (“no”), this is awaited in a step T8. In a step T9, a decision is made as to whether the process is complete. If not, it is repeated.

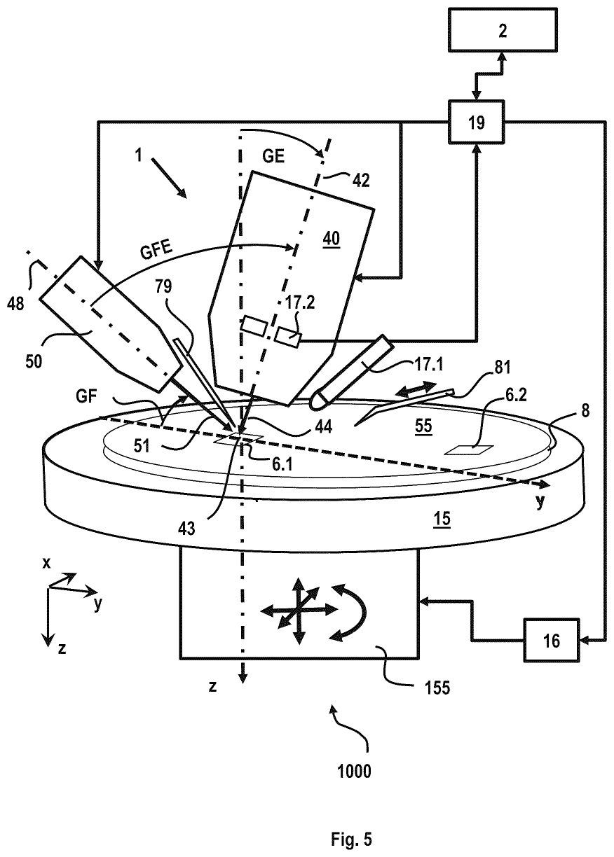

An example of a wafer inspection system 1000 for 3D volume inspection is illustrated in FIG. 5. The coordinate system is selected such that the wafer surface 55 coincides with the XY-plane.

For the investigation of 3D inspection volumes in semiconductor wafers, a slice and imaging method has been proposed, which is applicable to inspection of volumes inside a wafer. In an example, a 3D volume image is generated from an inspection volume inside a wafer by the so called “wedge-cut” approach or wedge-cut geometry, without the need of a removal of a sample piece from the wafer. The slice and image method is applied to an inspection volume with dimensions of few μm, for example with a lateral extension of 5 μm to 10 μm in wafers with diameters of 200 mm or 300 mm. The lateral extension can also be larger and reach up to 30 or 50 micrometers. A V-shaped groove or edge is milled in the top surface of an integrated semiconductor wafer to make accessible a cross-section surface at an angle to the top surface. 3D volume images of inspection volumes are acquired at a limited number of inspection sites, for example representative sites of dies, for example at process control monitors (PCM), or at sites identified by other inspection tools. The slice and image method will destroy the wafer only locally, and other dies may still be used, or the wafer may still be used for further processing. The methods and inspection systems according to the 3D Volume image generation are described in WO 2021/180600 A1, which is fully incorporated herein by reference.

The wafer inspection system 1000 is configured for a slice and imaging method under a wedge cut geometry with a dual beam system 1. For a wafer 8, several inspection sites, comprising inspection sites 6.1 and 6.2, are defined in a location map or inspection list generated from an inspection tool or from design information. The wafer 8 is placed on a wafer support table 15. The wafer support table 15 is mounted on a stage 155 with actuators and position control. Actuators and means for precision control for a wafer stage such as Laser interferometers are known in the art. A control unit 16 is configured to control the wafer stage 155 and to adjust an inspection site 6.1 of the wafer 8 at the intersection point 43 of the dual-beam device 1. The dual beam device 1 is comprising a focused ion beam (FIB) column 50 with a FIB optical axis 48 and a charged particle beam (CPB) imaging system 40 with optical axis 42. At the intersection point 43 of both optical axes of FIB and CPB imaging system, the wafer surface 55 is arranged at a slant angle GF to the FIB axis 48. FIB axis 48 and CPB imaging system axis 42 include an angle GFE, and the CPB imaging system axis forms an angle GE with the normal to the wafer surface 55. In the coordinate system of FIG. 5, the normal to the wafer surface 55 is given by the z-axis. The focused ion beam (FIB) 51 is generated by the FIB-column 50 and is impinging under angle GF on the surface 55 of the wafer 8. Slanted cross-section surfaces are milled into the wafer by ion beam milling at the inspection site 6.1 under approximately the slant angle GF. In the example of FIG. 5, the slant angle GF is approximately 30°. The actual slant angle of the slanted cross-section surface can deviate from the slant angle GF by up to 1° to 4° due to the beam divergency of the focused ion beam, for example a Gallium-Ion beam. The FIB column 50 can for example be a Gallium FIB, or a FIB with a gas field ion source (GFIS) with other kinds of ion species, such as Xenon or Argon ions. With the charged particle beam imaging system 40, inclined under angle GE to the wafer normal, images of the milled surfaces are acquired. In the example of FIG. 5, the angle GE is about 15°. However, other arrangements are possible as well, for example with GE=GF, such that the CPB imaging system axis 42 is perpendicular to the FIB axis 48, or GE=0°, such that the CPB imaging system axis 42 is perpendicular to the wafer surface 55.

During imaging, a beam of charged particles 44 is scanned by a scanning unit of the charged particle beam imaging system 40 along a scan path over a cross-section surface of the wafer 8 at inspection site 6.1, and secondary particles as well as scattered particles are generated. For example, secondary electron particle detector 17.1 collects at least some of the secondary particles and scattered particles and communicates the particle count with a control unit 19. Other detectors for other of interaction products may be present as well, for example in-lens detector 17.2 for collection of backscattered charged particles. Control unit 19 is in control of the charged particle beam imaging column 40 of FIB column 50 and connected to a stage control unit 16 to control the position of the wafer 8 mounted on the wafer support table 15 via the wafer stage 155. Control unit 19 communicates with operation control unit 2, which triggers placement and alignment for example of inspection site 6.1 of the wafer 8 at the intersection point 43 via wafer stage movement and triggers repeatedly operations of FIB milling, image acquisition and stage movements.

Each new intersection surface is milled by the FIB beam 51, and imaged by the charged particle imaging beam 44, which is for example scanning electron beam or a Helium-Ion-beam of a Helium ion microscope (HIM). In an example, the dual beam system comprises a first focused ion beam system 50 arranged at a first angle GF1 and a second focused ion column arranged at the second angle GF2, and the wafer is rotated between milling at the first angle GF1 and the second angle GF2, while imaging is performed by the imaging charged particle beam column 40, which is for example arranged perpendicular to the wafer surface 55.

The dual beam system 1 further comprises a gas injection system (GIS) 79, with a gas nozzle connected via a valve (not shown) to at least one gas reservoir (not shown). Thereby, controlled amounts of precursor gases can be provided during milling or imaging, and for example metal coatings can be generated. For example, alignment marks or fiducials can be generated. For example, a Tungsten metal coating is generated by providing Tungsten Hexacarbonyl. The metal coating can be shaped by ion beam milling and alignment markers or fiducials are formed in proximity to an inspection site. Thereby, a precise registration and image alignment of the plurality of cross section images is enabled. With dedicated precursor gases, a milling operation by FIB 51 can be enhanced. For example, a homogeneity of a milling operation in compositions of different material can be improved and curtaining can be reduced. Compositions of materials in a semiconductor wafer can comprise Silicon, Silicon Dioxide, Silicon Nitride, Copper, Aluminum, or other materials.

Preferred precursor gases are comprising at least one of Ammonia, Ammonium Hydroxide, Ammonium Carbamate, Bromine, Chlorine, Hydrazine, Hydrogen Peroxide, Hadacidin, Iodine, di-iodo-ethane, Isopropanol, Methyl Difluoroacetate, Nitroethane, Nitroethanol, Nitrogen, Nitrogen Tetroxide, Nitrogen Trifluoride, Nitromethane, Nitropropane, Nitrobutane, Oxygen, Ozone, PMCPS, Tungsten Hexacarbonyl, Water, or Xenon Difluoride. Other gases are, however, are possible as well, for example methoxy acetylchloride, methyl acetate, methyl nitroacetate, ethyl acetate, ethyl nitroacetate, propyl acetate, propyl nitroacetate, nitro ethyl acetate, methyl methoxyacetate, and methoxy acetylchloride, Acetic acid or thiolacetic acid, Hexafluoro-acetylacetone, silazane, trifluoroacetamide, dicobalt octacarbonyl, molybdenum hexa-carbonyl, and combinations thereof.

Furthermore, dual beam system 1 further comprises a contact pin 81. Contact pin 81 is connected to a manipulator (not shown) for precise movement of the contact pin 81, for example under control of the charged particle beam 44 during an image acquisition. Thereby, structures present on the wafer surface can be contacted and electrically connected to control device 19.

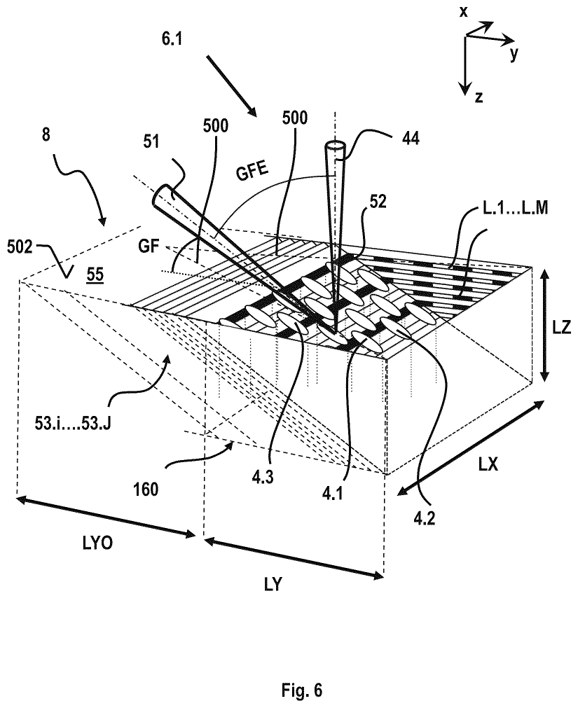

FIG. 6 illustrates the wedge cut geometry at the example of a 3D-memory stack. FIG. 6 illustrates the situation, when the surface 52 is the most recently milled cross-section surface which was milled by FIB 51. The cross-section surface 52 is scanned for example by SEM beam 44, which is in the example of FIG. 6 arranged at normal incidence to the wafer surface 55, and a high-resolution cross-section image slice is generated. The cross-section surfaces 53.1 . . . 53.N are subsequently milled with a FIB beam 51 at an angle GF of approximately 30° to the wafer surface 55, but other angles GF, for example between GF=20° and GF=60° are possible as well. The cross-section image slice comprises first cross-section image features, formed by intersections with high aspect ratio (HAR) structures or vias (for example first cross-section image features of HAR-structures 4.1, 4.2, and 4.3) and second cross-section image features formed by intersections with layers L.1 . . . L.M, which comprise for example SiO2, SiN— or Tungsten lines. Some of the lines are also called “word-lines”. The maximum number M of layers is typically more than 50, for example more than 100 or even more than 200. The HAR-structures and layers extend throughout most of the volume in the wafer but may comprise gaps. The HAR structures typically have diameters below 100 nm, for example about 80 nm, or for example 40 nm. The cross-section image slices contain therefore first cross-section image features as intersections or cross-sections of the HAR structures at different depth (Z) at the respective XY-location. In case of vertical memory HAR structures of a cylindrical shape, the obtained first cross-sections image features are circular or elliptical structures at various depths determined by the locations of the structures on the sloped cross-section surface 52.

The memory stack extends in the Z-direction perpendicular to the wafer surface 55. The thickness d or minimum distances d between two adjacent cross-section image slices is adjusted to values typically in the order of few nm, for example 30 nm, 20 nm, 10 nm, nm, 4 nm or even less. Once a layer of material of predetermined thickness d is removed with FIB, a next cross-section surface 53.i . . . 53.J is exposed and accessible for imaging with the charged particle imaging beam 44. During repeated milling and imaging, a plurality of cross sections is formed, and a plurality of cross section images are obtained, such that an inspection volume of size LX×LY×LZ is properly sampled and for example a 3D volume image can be generated. Thereby, the damage to the wafer is limited to the inspection volume 160 plus a damaged volume in y-direction of length LYO. With an inspection depth LZ about 10 μm, the additional damage volume in y-direction is typically limited to below 20 μm.

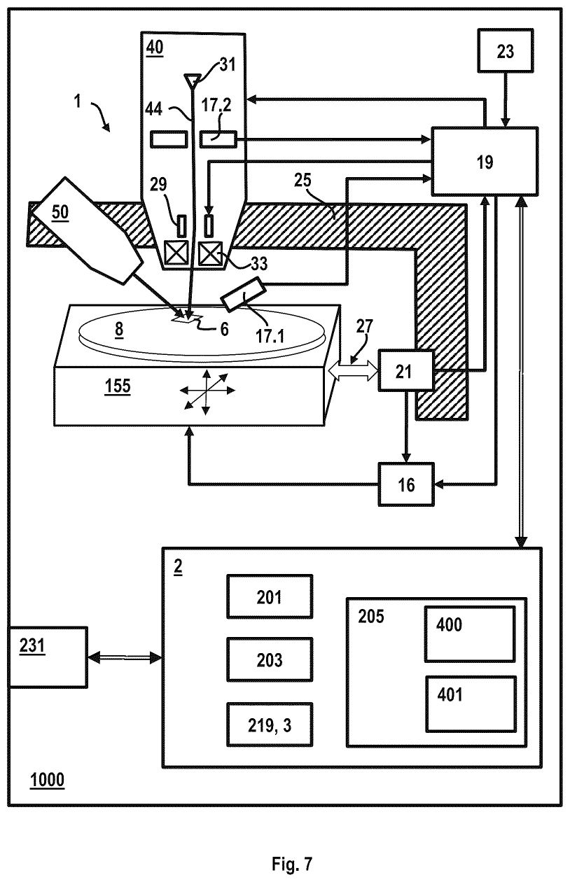

A further example of an improved wafer inspection system is illustrated in FIG. 7. The wafer inspection system 1000 is comprising a dual beam system 1. A dual beam system is illustrated in FIG. 5 and reference is also made to the description of FIG. 5. Essential features of a dual beam system 1 may include a first charged particle or FIB column 50 for milling and a second, charged particle beam imaging system 40 for high-resolution imaging of cross section surfaces. A dual beam system 1 comprises at least one detector 17 for detecting secondary particles, which can be electrons or photons. In the example, a first detector 17.1 is arranged close to the interaction volume of the primary beam 44 with the wafer 8 and configured to attract and collect secondary electrons. A second, in-lens detector 17.2 is arranged within the imaging charged particle beam system 40 and configured to collect backscattered electrons. A dual beam system 1 further comprises a wafer stage 155 configured for holding during use a wafer 8. The wafer stage 155 comprises actuators for lateral and axial displacement or rotation of the wafer stage 155. For example, a wafer stage comprises long stroke actuators for displacements of the wafer 8 from a first inspection site 6.1 to a second inspection site 6.2 (see FIG. 5) and short stroke actuators of high precision for precision adjustment of the wafer 8 at an inspection position. The degrees of freedom for position adjustment and movement of the wafer stage 155 can be between three (x,y, rotation around z-axis) and all six degrees of freedom. The dual beam system 1 further comprises a control unit 19. The control unit 19 is configured with memory and logic to control operation of the dual beam system 1.

The wafer stage 155 is position controlled by a stage control unit 16, which is connected to a high precision position sensor 21 configured for measuring during use the position of the wafer stage 155 relative to the charged particle beam imaging system 40 in at least two degrees of freedom (x,y). In an example, the charged particle beam imaging system 40 and the high precision position sensor 21 are mounted on a rigid support or metrology frame 25, which acts as a reference for the relative position measurement between wafer stage 155 and charged particle imaging beam 44. Examples of precision position sensor 21 comprise Laser interferometers, grid interferometers, capacitive sensors or confocal sensors. Precision position sensor 21 is configured for performing during use at least one position measurement 27 of the position of the wafer stage 155 with respect to the metrology frame 25.

During use, charged particle beam source 31 generates charged particles. The dual beam system 1 further comprises a deflection scanner 29 for raster scanning the charged particle imaging beam 40. The dual beam system 1 further comprises an objective lens 33 for focusing the charged particle imaging beam 40 onto a cross-section surface 53. Deflection scanner 29 and objective lens 33 are connected and controlled by control unit 19.

The dual beam system 1 of the example illustrated in FIG. 7 further comprises a condition monitor 23, which is configured as a measurement system for measurements of environmental influences during the image acquisition. Condition monitor 23 comprises at least one of a group of measurement systems including an electromagnetic field sensor, a vibration sensor, a temperature sensor, a gravitation sensor. Condition monitor 23 is connected to control unit 19 and configured to provide during image acquisition a plurality of measurements of environmental influences during images scanning at a plurality of representative dwell points.

The wafer inspection system 1000 is further comprising an operation control unit 2. The operation control unit 2 comprises at least one processing engine 201, which can be formed by multiple parallel processors including GPU processors and a common, unified memory. The operation control unit 2 further comprises an SSD memory or disk memory or storage 203 for storing data, for example including training data and a trained machine learning algorithm, and a plurality of cross-section images. The operation control unit 2 further comprises a user interface 205, comprising the user interface display 400 and user command devices 401, configured for receiving input from a user and display quotes or results to a user. The operation control unit 2 further comprises a memory or storage 219 for storing process information of the image generation process of the dual beam device 1 and for storing software instructions 3, which can be executed by the processing engine 201.

The operation control unit 2 is further connected to an interface unit 231, which is configured to receive further commands or data, for example CAD data, from external devices or a network. The interface unit 231 is further configured to exchange information, for example receive instructions from external devices or provide measurement results to external devices or store a set of training data or a trained machine learning algorithm or plurality of cross section images in external storages.

The operation control unit 2 is connected to dual beam system 1 and configured to receive a plurality of two-dimensional images of a plurality of cross section surfaces. The operation control unit 2 is configured to determine a three-dimensional (3D) volume image of the inspection volume 160 from the plurality of two-dimensional images of a plurality of cross section surfaces.

The wafer inspection system 1000 is configured to receive user information for execution of a measurement task, for example comprising CAD information of the semiconductor object of interest, the location of the inspection site, or the inspection result. The processing engine 201 is configured to compute and display information via the user display 400 and to receive user input via user interface 401.

All features, method steps and advantages explained herein in respect of the apparatus 100 and steps S1-S6 equally apply to the apparatus/system 1000 and steps S2′-S4, and vice versa. Faults may be characterized in the apparatuses or systems 100, 1000 in the same or substantially the same manner.

According to an embodiment, there is provided a method of characterizing a fault in a scanning electron microscope 100, wherein the scanning electron microscope 100 is suitable for analyzing and/or processing a sample 8, 10, especially a wafer or lithography mask, with the aid of an electron beam 106, wherein the method has the following steps:
introducing S2′ (see FIG. 3) a trigger event into the scanning electron microscope 100,
detecting S3 a response behaviour of the scanning electron microscope 100 to the trigger event, and
comparing S4 the response behaviour detected with an expected response behaviour for characterization of the fault.

Advantageously, this embodiment does not rely on a prior equilibrium state (step S1 of the previous embodiment). Still, all embodiments and features explained above in regard to the method steps S1-S4 equally applies to this method (steps S2′-S4).

According to an embodiment, step S2 or S2′ includes introducing a sequence of trigger events into the scanning electron microscope 40, 100. By using a sequence, the fault can be characterized in a more reliable/safer way.

According to an embodiment, the trigger event or a or each trigger event in a sequence of trigger events is an event occurring during operation of the scanning electron microscope 40, 100. This may be a normal operation of the scanning electron microscope. Advantageously, not an “extra” trigger is needed to characterize the system, but triggers that occur naturally in operation of the electron microscope 40, 100 can be used.

According to an embodiment, the operation preferably includes one or more of the following:
a start-up phase during which the scanning electron microscope 40, 100 is started up, the start-up phase in particular including opening of a column isolation valve 230 (see FIG. 2) of the scanning electron microscope 40, 100 and/or applying an acceleration voltage to one or more electrodes 104 of the scanning electron microscope 40, 100,
an analysis phase during which the sample 8, 10 is analyzed using the scanning electron microscope 100, the analysis phase in particular including recording one or more images of the sample 8, 10 using the scanning electron microscope 40, 100,
a processing phase during which the sample 8, 10 is processed using the scanning electron microscope 40, 100, the processing phase in particular including depositing material on and/or etching material from the sample 8, 10 and/or milling the sample 8 using an ion beam 51 and/or recording one or more images of the sample 8, using the scanning electron microscope 40, 100, and/or
a sample transfer phase during which the sample 8, 10 is transferred 238 into or out of the scanning electron microscope 100, the sample transfer phase in particular including switching off an acceleration voltage applying to one or more electrodes 104 of the scanning electron microscope 40, 100, closing a column isolation valve 230 of the scanning electron microscope 40, 100 and/or opening a sluice 232 (see FIG. 2) in a vacuum housing 110 of the scanning electron microscope 40, 100 to transfer the sample 8, 10.

These are examples of phases where one or more trigger events occur naturally, i.e., as part of the normal system operation. Any abnormalities thus detected in step S4 thus indicate that there may be a problem.

According to an embodiment, the trigger event or sequence of trigger events includes one or more of the following triggers:
admission of gases, comprising preferably carbon compounds or a tungsten precursor, for writing the pads 502, including preferably a layer made of carbon and tungsten (thus a good contrast is ensured), and position marks 500 on the pads 502 (based on the position marks 500 the milling progress, in particular depth, can be determined; the position marks 500 in different images taken with the SEM 40 allow to determine the milling progress easily),
retracting and/or extending the gas injection needle 79 (for injecting process gas, for example),
setting a sample current 228 to write position marks 500 on pads 502, the sample current being preferably larger than 1 or 4 Nanoampere,
setting a landing energy (i.e. the energy with which particles land on the sample 8, 10), the landing energy being for example low including a range of, e.g., 500-1000 eV, and/or high including a range of, e.g., 15,000-30,000 eV,
beam blanking during imaging, e.g. at the end of a scan line, (in this case a short beam blank can be used, e.g., using the electrodes 234, see FIG. 2, to avoid contamination)
beam blanking during FIB processing, (in this case a long beam blank can be used, e.g., using the coils 234 (instead of electrodes), see FIG. 2)
turning off the acceleration voltage during FIB processing,
admission of auxiliary gases during FIB processing, e.g. H2O, O2, N2 and/or XeF2, and/or
FIB processing, e.g., release of secondary electrons by FIB processing interacting with the scanning electron microscope 40.

According to an embodiment, the method further comprises:
if in the step of comparing S4 an unexpected response behaviour is determined, one or more additional trigger events are searched for and if such additional trigger events are detected, a warning is output and/or steps S1-S4 or S2′-S4 are repeated and/or operation of the scanning electron microscope 100 is halted or aborted.

Some of the trigger events may be difficult to separate and analyze in a running process as they are likely to occur simultaneously. It may therefore be advantageous to make the method executable in separate modules. For example, a rough procedure that runs “online” and searches for unexpected answers for a list of triggers that occur in the process, and then issues a warning that a service call/the complete procedure is necessary (yellow light) or the process aborts (red light). It would also be conceivable to evaluate partial data as “suspicious” where the system response was unusual (e.g., increased beam drift in the mapping according to blanking for the FIB processing).

For example in step S3 and/or S4, the position of the electron beam may be plotted as a function of time relative to a second imaging method independent of the electron beam, e.g., the focused ion beam; relative to previously placed alignment marks 500; or the sample position (i.e. the position of the sample stage 15, 112) can be determined. Simultaneous imaging with secondary ions and backscattered primary electrons may allow, for example, beam drift to be distinguished from stage drift (no laser interferometry present or defective, for example). However, simultaneous imaging with ions and electrons may form another trigger event.

In addition, the occurrence of image line jumps or ripple could be detected. Image line jumps are very fast, discrete position changes in contrast to slow, global image drift. Image line jumps could, for example, be triggered by microarcing (defective insulation distances), which can occur at very high voltages. Furthermore, a deformation of the scan field could be recorded (e.g. magnification, trapezium/cushion or non-linear deformations). This could be caused by charges underneath the scan system or a change in the temperature of the scan system after setting a minimum/maximum magnification.

| | Trigger event (right): | | | | |
|---|---|---|---|---|---|
| | | | High | High | Acceleration |
| Type of | | Beamshift | sample | acceleration | Voltage |
| fault (below): | Beamblank | Scansystem | current | voltage | switched off |
| Particle 236 | ++ | +++ | ++ | + | + |
| in lens 218, | | | | | |
| 222 | | | | | |
| Particle in | +++ | − | +++ | ++ | ++ |
| detector | | | | | |
| 214, 216 | | | | | |
| Particle in | − | − | +++ | ++ | ++ |
| aperture | | | | | |
| stop 202 | | | | | |
| Particle in | − | − | − | +++ | ++ |
| anode 200 | | | | | |
| Particle in | − | − | − | − | +++ |
| emitter 104 | | | | | |
| Defective | − | − | − | +++ | ++ |
| high voltage | | | | | |
| (up to 30 | | | | | |
| kV) isolation | | | | | |

According to a further aspect, there is provided an apparatus, comprising:
a charged particle beam imaging system 40, 100,
a detector unit 17.2, 102 for detecting a response behaviour of the charged particle beam imaging system 40, 100 to the trigger event, and
a control unit 2, 120 for comparing the response behaviour detected with an expected response behaviour for characterization of a fault.

According to an embodiment, the apparatus is configured as a mask repair system 100 or a wafer inspections system 1000.

According to an embodiment, the charged particle beam imaging system comprising a scanning electron microscope 40, 100, a FIB column 50 and/or dual-beam system 1.

According to a further aspect, there is provided an apparatus, comprising:
a charged particle beam imaging system 40, 100, and
a control unit 2, 120 being configured for implementing the method as described above.

Although the present invention has been described with reference to exemplary embodiments, it can be modified in various ways.

### LIST OF REFERENCE SIGNS

10 Lithography mask
10′ Reference object
100 Processing arrangement
102 Electron column
104 Electron source
106 Electron beam
108 Detector unit
110 Vacuum housing
112 Sample stage
114 Vacuum pump
116 Gas provision unit
118 Gas conduit
120 Control computer
122 Computer program product
200 Anode stop
202 Aperture stop
204 Beam path section
206 Condenser
207 Condenser
208 Double condenser
210 Stop
212 Beam path section
214 ESB detector
216 SE detector
220 Filter grid
221 Magnetic lens
222 Scanner coils
226 Electrostatic lens
228 sample current
230 column isolation valve
232 sluice
234 beam guiding means
236 particle
238 sample transfer
1 dual beam device
2 operation control unit
3 software instructions
4.1 HAR structure
4.2 HAR structure
4.3 HAR structure
6.1 inspection site
6.2 inspection site
8 wafer
15 wafer support table
16 stage control unit
17.1 secondary electron particle detector
17.2 in-lens detector
19 control unit
21 high precision position sensor
23 condition monitor
25 metrology frame
27 metrology frame
29 deflection scanner
31 charged particle beam source
33 objective lens
40 CPB imaging system
42 CPB imaging system axis
43 intersection point
44 beam of charged particles
48 FIB axis
50 FIB column
51 FIB ion beam
52 cross section surface
53.i . . . 53.j cross section surfaces
55 wafer surface
79 GIS
81 contact pin
155 wafer stage
160 inspection volume
201 processing engine
203 storage
205 user interface
219 storage
231 interface unit
400 user display
401 user command devices
500 position mark
502 pad
1000 wafer inspection system
GE angle
GFE angle
GE angle
L.1 . . . L.M layers
S1-S6 Method steps
T1-T9 Method steps

What is claimed is:

1. A method of characterizing a fault in a scanning electron microscope, wherein the scanning electron microscope is suitable for analyzing and/or processing a sample with the aid of an electron beam, wherein the method has the following steps:
a) putting the scanning electron microscope in an equilibrium state,
b) introducing a trigger event into the scanning electron microscope that disrupts the equilibrium state,
c) detecting a response behaviour of the scanning electron microscope to the trigger event, and
d) comparing the response behaviour detected with an expected response behaviour for characterization of the fault.

2. The method according to claim 1, wherein a number N of images is recorded in step a).

3. The method according to claim 1, wherein a position and/or a sharpness of the electron beam is recorded in step a) as a function of time and compared with a threshold value, and commencement of step b) is dependent on the comparison.

4. The method according to claim 1, wherein the response behaviour detected in step c) is a position, a focus, a stigmator and/or a coma of the electron beam as a function of time.

5. The method according to claim 1, wherein the trigger event comprises: an altered sample current, an altered acceleration voltage, parts of switch-on sequences, a change in a process gas composition or a process gas pressure and/or a change in the electron beam cross section or in a position of the electron beam.

6. The method according to claim 1, wherein steps a) to d) are conducted for a first trigger event and repeated for a second trigger event, wherein the first and second trigger events are chosen such that an electron dose at a first site within the beam path of the electron beam has a first value on occurrence of the first trigger event and has a second value different from the first value on occurrence of the second trigger event, and an electron dose at a second site within the beam path of the electron beam has a first value on occurrence of the first trigger event and a second value equal to the first value on occurrence of the second trigger event, wherein, in a step that follows step d), the fault is assigned to the first site depending on the comparison in step d) for the first and second trigger events.

7. The method according to claim 6, wherein
(i) the first trigger event comprises focusing of the electron beam by use of an anode stop and/or aperture stop, wherein the sample current is collected in a Faraday cup, and the second trigger event comprises trimming the electron beam with the aid of the anode stop and/or aperture stop, wherein the sample current is likewise collected in the Faraday cup,
(ii) the first trigger event comprises a change in current at the electron source for generation of the electron beam and the second trigger event comprises an increase in the sample current with the aid of a condenser excitation,
(iii) the first trigger event comprises passage of the electron beam through a stop and the second trigger event comprises an increase in the sample current, and/or
(iv) the first trigger event comprises complete covering of the electron beam at the stop and the second trigger event comprises collecting of the electron beam in a Faraday cup.

8. The method according to claim 1, wherein the response behaviour in steps c) and/or d) comprises a vertical displacement and/or decay characteristics.

9. The method according to claim 1, wherein steps a) to d) are performed in a fully automated manner.

10. A method of characterizing a fault in a scanning electron microscope, wherein the scanning electron microscope is suitable for analyzing and/or processing a sample, especially a wafer or lithography mask, with the aid of an electron beam, wherein the method has the following steps:
b1) introducing a trigger event into the scanning electron microscope,
c1) detecting a response behaviour of the scanning electron microscope to the trigger event, and
d1) comparing the response behaviour detected with an expected response behaviour for characterization of the fault.

11. The method according to claim 1, wherein step b) or b1) includes introducing a sequence of trigger events into the scanning electron microscope.

12. The method according to claim 1, wherein the trigger event or a or each trigger event in a sequence of trigger events is an event occurring during operation of the scanning electron microscope.

13. The method according to claim 1, wherein the trigger event or sequence of trigger events includes one or more of the following triggers:
admission of gases,
retracting and/or extending a gas injection needle,
setting a sample current to write position marks on pads,
setting a landing energy,
beam blanking during imaging,
beam blanking during FIB processing,
turning off the acceleration voltage during FIB processing,
admission of auxiliary gases during FIB processing, and/or
FIB processing.

14. The method according to claim 1, further comprising:
if in the step of comparing an unexpected response behaviour is determined, one or more additional trigger events are searched for and if such additional trigger events are detected, a warning is output and/or steps a)-d) or b1)-d1) are repeated and/or operation of the scanning electron microscope is halted.

15. An apparatus, comprising:
a charged particle beam imaging system,
a detector unit configured to detect a response behaviour of the charged particle beam imaging system to the trigger event, and
a control unit configured to compare the response behaviour detected with an expected response behaviour for characterization of a fault.

16. The apparatus of claim 15, wherein the apparatus is configured as a mask repair system or a wafer inspections system.

17. The apparatus of claim 15, the charged particle beam imaging system comprising a scanning electron microscope, a FIB column and/or dual-beam system.

18. An apparatus, comprising:
a charged particle beam imaging system, and
a control unit being configured for implementing a method of characterizing a fault in a scanning electron microscope, wherein the scanning electron microscope is suitable for analyzing and/or processing a sample with the aid of an electron beam, wherein the method has the following steps:
a) putting the scanning electron microscope in an equilibrium state,
b) introducing a trigger event into the scanning electron microscope that disrupts the equilibrium state,
c) detecting a response behaviour of the scanning electron microscope to the trigger event, and
d) comparing the response behaviour detected with an expected response behaviour for characterization of the fault.

19. A computer program product, comprising commands which, when the program is executed by a computer, cause the latter to execute a method of characterizing a fault in a scanning electron microscope, wherein the scanning electron microscope is suitable for analyzing and/or processing a sample with the aid of an electron beam, wherein the method has the following steps:
a) putting the scanning electron microscope in an equilibrium state,
b) introducing a trigger event into the scanning electron microscope that disrupts the equilibrium state,
c) detecting a response behaviour of the scanning electron microscope to the trigger event, and
d) comparing the response behaviour detected with an expected response behaviour for characterization of the fault.

20. The method according to claim 12, wherein the operation comprises one or more of the following:
a start-up phase during which the scanning electron microscope is started up, the start-up phase including opening of a column isolation valve of the scanning electron microscope and/or applying an acceleration voltage to one or more electrodes of the scanning electron microscope,
an analysis phase during which the sample is analyzed using the scanning electron microscope, the analysis phase including recording one or more images of the sample using the scanning electron microscope,
a processing phase during which the sample is processed using the scanning electron microscope, the processing phase including depositing material on and/or etching material from the sample and/or milling the sample using an ion beam and/or recording one or more images of the sample using the scanning electron microscope, and/or
a sample transfer phase during which the sample is transferred into or out of the scanning electron microscope, the sample transfer phase including switching off an acceleration voltage applying to one or more electrodes of the scanning electron microscope, closing a column isolation valve of the scanning electron microscope and/or opening a sluice in a vacuum housing of the scanning electron microscope to transfer the sample.
